(19) United States
(12) Patent Application Publication
(10) Pub. No.: US 2020/0203543 A1
(43) Pub. Date: Jun. 25, 2020

(54) BIFACIAL DOUBLE GLASS SOLAR MODULE

(71) Applicant: Worldwide Energy and Manufacturing (Nantong) Co., Ltd., Rugao City (CN)

(72) Inventors: Jianjun WANG, Rugao City (CN); Zhaowei NING, Rugao City (CN); Tao FENG, Rugao City (CN); Congwu LIANG, Rugao City (CN); Jianchao ZHANG, Rugao City (CN); Taohua HUANG, Rugao City (CN); Yun SHI, Rugao City (CN); Dong TANG, Rugao City (CN)

(21) Appl. No.: 16/707,518

(22) Filed: Dec. 9, 2019

(30) Foreign Application Priority Data
Dec. 25, 2018 (CN) 201822191961.1

(51) Int. Cl. H01L 31/048; H01L 31/05; H01L 31/0216; H01L 31/068; H01L 31/055; H01L 31/18

(52) U.S. Cl. CPC H01L 31/0488; H01L 31/0508; H01L 31/1804; H01L 31/0684; H01L 31/055; H01L 31/02168

(57) ABSTRACT

A bifacial double glass solar module including: the upper glass layer, the upper encapsulation layer, the cell layer, the lower encapsulation layer, and the lower glass layer. The upper glass layer, the upper encapsulation layer, the cell layer, the lower encapsulation layer, and the lower glass layer are disposed sequentially from top to bottom. The cell layer includes a plurality of double-sided cells connected in series by a solder strip. The upper glass layer is provided with a first anti-reflection film layer on the upper surface and a first up-conversion thin film layer on the lower surface. The lower glass layer is provided with a second up-conversion thin film layer on the upper surface and a second anti-reflection film layer on the lower surface.

### CROSS-REFERENCE TO RELATED APPLICATIONS

This application claims the benefit of priority of Chinese Application No. 201822191961.1, titled “BIFACIAL DOUBLE GLASS SOLAR MODULE,” filed on Dec. 25, 2018, which is hereby incorporated by reference in its entirety.

### BACKGROUND

### Technical Field

The disclosure relates to the technical field of solar energy technologies, and in particular, to bifacial double glass solar module technologies.

### Description of the Related Art

With the depletion of traditional fossil energy sources and the growing environmental problems, energy problems have become a serious challenge for countries all over the world. As alternative energy sources for fossil fuels, renewable energy sources are clean, pollution-free, renewable, and in line with the requirements of sustainable development, thus being favored by many countries as an important part of their energy development strategies. Among them, solar photovoltaic power generation is the fastest developing and most dynamic field in recent years. As a clean and green renewable energy source, solar energy has received increasingly more attention and is applied more widely. In addition to the conventional photothermal conversion, one of the most important applications of solar energy is photovoltaic power generation.

Most of the currently widely used photovoltaic modules are single-sided modules, and the single-sided module uses single-sided solar cells. Since the solar cell of this structure can absorb only light from the front side, and the back side cannot absorb light, the power output of the single-sided cell is relatively limited. In contrast, compared with the single-sided solar cell, a double-sided solar cell can absorb light on both sides, thus greatly increasing the overall power output and the conversion efficiency of the cell. In recent years, double-sided photovoltaic modules have become the main choice for today's photovoltaic power plants to increase power generation and increase investment returns because of their various advantages such as high-power generation, high reliability, and a plurality of application scenarios.

For example, the front side of the double-sided solar module can generate electricity by receiving direct sunlight, and the back side can generate electricity by absorbing the reflected light from the background and the scattered light around it. The solar spectrum has a wavelength range of 150 nm to 4000 nm and contains ultraviolet light, visible light, and infrared light, where 7% of the solar radiation energy is distributed in the ultraviolet spectral region, 50% in the visible spectral region, and 43% in the infrared spectral region. For infrared light with a wavelength greater than 1200 nm in the solar spectrum, a photo-generated current cannot be generated in the cell since the photon energy is smaller than the band gap width of silicon. This part of the light can only be converted into heat, thereby raising the temperature of the cell and reducing the conversion efficiency of the module. Therefore, how to improve the utilization rate of light energy on the front and back sides of the double-sided solar cell is a technical problem to be solved urgently.

### SUMMARY

Embodiments of the disclosure provide a bifacial double glass solar module in view of the above problems. In some embodiments, by disposing an anti-reflection film layer and an up-conversion thin film layer on each of an upper glass layer and a lower glass layer of the module, the light transmittance of front and back sides can be increased on one hand, and on the other hand, the infrared light in the incident solar spectrum can be converted into visible light causing a higher response of the cell, thereby increasing the output power and the conversion efficiency of the module.

Embodiments of the disclosure can be implemented as follows: a bifacial double glass solar module, including an upper glass layer, an upper encapsulation layer, a cell layer, a lower encapsulation layer, and a lower glass layer disposed sequentially from top to bottom, wherein the cell layer can include a plurality of double-sided cells connected in series by a solder strip, the upper glass layer can be provided with a first anti-reflection film layer on the upper surface and a first up-conversion thin film layer on the lower surface, and the lower glass layer can be provided with a second up-conversion thin film layer on the upper surface and a second anti-reflection film layer on the lower surface.

For example, the first anti-reflection film layer and the second anti-reflection film layer can be composed of one or more of SiO2, TiO2, SiNx, Al2O3, MgF2, and ZrO2.

In some embodiments, the first anti-reflection film layer and the second anti-reflection film layer can have a thickness of 50 nm to 800 nm.

For example, the first up-conversion thin film layer and the second up-conversion thin film layer can be composed of a Yb3+, Er3+co-doped fluoride, a Yb3+, Tm3+co-doped fluoride, an Er3+single-doped fluoride, or a Tm3+single-doped fluoride.

In some embodiments, the first up-conversion thin film layer and the second up-conversion thin film layer can be composed of a Yb3+, Er3+co-doped oxide, a Yb3+, Tm3+co-doped oxide, an Er3+single-doped oxide, or a Tm3+single-doped oxide.

For example, the first up-conversion thin film layer and the second up-conversion thin film layer can have a thickness of 100 nm to 600 nm.

In some embodiments, the double-sided cell can be an N-type double-sided cell or a P-type double-sided cell.

For example, the double-sided cell can be a whole cell or a sliced cell.

Compared with the prior art, embodiments of the disclosure have the advantage that the efficient utilization of the solar spectrum is achieved by disposing a plurality of functional thin film layers on the upper glass layer and the lower glass layer. For example, the anti-reflection film layers disposed on the upper surface of the upper glass layer and the lower surface of the lower glass layer not only can reduce the reflection of light, but also can increase the utilization rate of the module regarding the incident light on the front side and the reflected light and the scattered light on the back side, and the anti-reflection film can effectively improve the self-cleaning ability of the module. In some embodiments, the up-conversion thin film layers disposed on the lower surface of the upper glass layer and the upper surface of the lower glass layer can convert, via the up-conversion process, infrared light that cannot be absorbed by the silicon solar cell into visible light causing a higher response of the cell, thus increasing the photo-generated current. In addition, since the infrared light is used, the temperature of the cell can be lowered indirectly, and the output power and the conversion efficiency of the module can be greatly improved.

The above description is merely an overview of the technical solutions of this disclosure. In order for people skilled in the art to better understand the technical means of the disclosure so that the technical solutions may be implemented more clearly and easily, the above description, other objectives, features, and advantages of the disclosure are illustrated in the following content of the specification. The embodiments of the disclosure are specifically described in what follows.

### BRIEF DESCRIPTION OF THE DRAWINGS

The accompanying drawings illustrated herein are to provide a further understanding of the disclosed embodiments and constitute a part of the disclosure. Illustrative embodiments of the disclosure and their descriptions are intended to explain the disclosed embodiments rather than unduly limit the embodiments.

FIG. 1 is a cross-sectional diagram of a bifacial double glass solar module according to some embodiments of the disclosure.

FIG. 2 is a cross-sectional diagram of an upper glass layer according to some embodiments of the disclosure.

FIG. 3 is a cross-sectional diagram of a lower glass layer according to some embodiments of the disclosure.

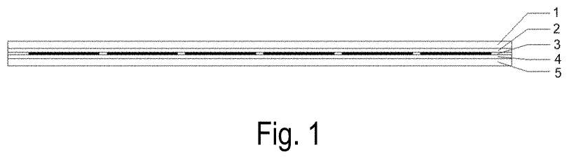

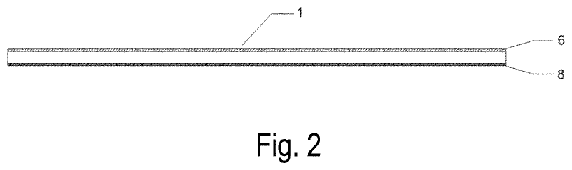

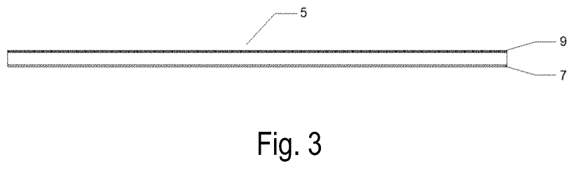

According to some embodiments of the disclosure, as shown in FIG. 1-3, the layer 1 denotes an upper glass layer; the layer 2 denotes an upper encapsulation layer; the layer 3 denotes a cell layer; the layer 4 denotes a lower encapsulation layer; the layer 5 denotes a lower glass layer; the layer 6 denotes a first anti-reflection film layer; the layer 7 denotes a second anti-reflection film layer, the layer 8 denotes a first up-conversion thin film layer; the layer 9 denotes a second up-conversion thin film layer.

### DETAILED DESCRIPTION

Exemplary embodiments of the disclosure will be described below in more detail with reference to the accompanying drawings. Although the accompanying drawings show exemplary embodiments, it should be understood that the disclosed embodiments may be implemented in various forms and should not be limited by the specific embodiments described herein. Instead, the disclosed embodiments are provided so that the disclosure will be better understood, and the scope of the disclosure can be fully conveyed to a person skilled in the art.

In some embodiments, as shown in FIG. 1-3, a bifacial double glass solar module can include an upper glass layer 1, an upper encapsulation layer 2, a cell layer 3, a lower encapsulation layer 4, and a lower glass layer 5 disposed sequentially from top to bottom. For example, the cell layer can include a plurality of double-sided cells connected in series by a solder strip. In some embodiments, the upper glass layer 1 can be provided with a first anti-reflection film layer 6 on the upper surface and a first up-conversion thin film layer 8 on the lower surface, and the lower glass layer is provided with a second up-conversion thin film layer 9 on the upper surface and a second anti-reflection film layer 7 on the lower surface.

In some embodiments, the anti-reflection film layers disposed on the upper surface of the upper glass layer and the lower surface of the lower glass layer can be composed of one or more of SiO2, TiO2, SiNx, Al2O3, MgF2, and ZrO2. For example, the anti-reflection film layer can be a single-layer thin film or a multi-layer thin film. In some embodiments, the anti-reflection film layer can utilize the interference effect produced by different optical thin films to eliminate the reflected light, to improve the light transmittance of the glass to a certain extent, and to increase the utilization rate of the module regarding the incident light on the front side and the reflected light and the scattered light on the back side. Further, for example, the anti-reflection thin film can change the hydrophilicity of the glass surface layer, improve the self-cleaning performance of the glass, reduce the use of a cleaning agent, keeps the glass clean persistently, and improve the conversion efficiency of the module. Furthermore, in some embodiments, the anti-reflection thin film also can improve the acid, alkali and aging resistance, improve the weatherability, protect the glass, and prolong the service life of the module.

For example, the up-conversion thin film layers disposed on the lower surface of the upper glass layer and the upper surface of the lower glass layer can be composed of a Yb3+, Er3+co-doped fluoride, a Yb3+, Tm3+co-doped fluoride, an Er3+single-doped fluoride, or a Tm3+single-doped fluoride, or a Yb3+, Er3+co-doped oxide, a Yb3+, Tm3+co-doped oxide, an Er3+single-doped oxide, or a Tm3+single-doped oxide. In some embodiments, the up-conversion thin film layer can convert, via the up-conversion process, infrared light that cannot be absorbed by the silicon solar cell into visible light causing a higher response of the cell, thus greatly improving the spectral response of the double-sided cell to the incident light on the front side and the reflected light and the scattered light on the back side, and increasing the photo-generated current of the cell. In addition, for example, since the infrared light in the incident light is converted, the thermal effect brought by the infrared light is greatly reduced, thereby indirectly lowering the temperature of the cell, and ultimately greatly improving the output power and the conversion efficiency of the module.

The above implementations are merely exemplary implementations employed to explain the principles of the current disclosure, and the current disclosure is not limited thereto. For a person skilled in the art, various changes or improvements can be made according to the above-mentioned content of the current disclosure, according to the prior art and knowledge in the art, and with reference to the basic idea of the current disclosure. Such changes or improvements should fall within the protection scope of the current disclosure.

What is claimed is:

1. A bifacial solar module, comprising:
an upper glass layer;
an upper encapsulation layer;
a cell layer;
a lower encapsulation layer; and
a lower glass layer.

2. The bifacial solar module according to claim 1, wherein the upper glass layer, the upper encapsulation layer, the cell layer, the lower encapsulation layer, and the lower glass layer are disposed sequentially from top to bottom.

3. The bifacial solar module according to claim 1, wherein the cell layer comprises a plurality of double-sided cells connected in series by a solder strip.

4. The bifacial solar module according to claim 1, wherein the upper glass layer is provided with a first anti-reflection film layer on the upper surface and a first up-conversion thin film layer on the lower surface.

5. The bifacial solar module according to claim 1, wherein the lower glass layer is provided with a second up-conversion thin film layer on the upper surface and a second anti-reflection film layer on the lower surface.

6. The bifacial solar module according to claim 1, wherein the first anti-reflection film layer and the second anti-reflection film layer are composed of one or more of SiO2, TiO2, SiNx, Al2O3, MgF2, and ZrO2.

7. The bifacial solar module according to claim 1, wherein the first anti-reflection film layer and the second anti-reflection film layer have a thickness of 50 nm to 800 nm.

8. The bifacial solar module according to claim 1, wherein the first up-conversion thin film layer and the second up-conversion thin film layer are composed of a Yb3+, Er3+co-doped fluoride, a Yb3+, Tm3+co-doped fluoride, an Er3+single-doped fluoride, or a Tm3+single-doped fluoride.

9. The bifacial solar module according to claim 1, wherein the first up-conversion thin film layer and the second up-conversion thin film layer are composed of a Yb3+, Er3+co-doped oxide, a Yb3+, Tm3+co-doped oxide, an Er3+single-doped oxide, or a Tm3+single-doped oxide.

10. The bifacial solar module according to claim 1, wherein the first up-conversion thin film layer and the second up-conversion thin film layer have a thickness of 100 nm to 600 nm.

11. The bifacial solar module according to claim 1, wherein the double-sided cell is an N-type double-sided cell or a P-type double-sided cell.

12. The bifacial solar module according to claim 1, wherein the double-sided cell is a whole cell or a sliced cell.

13. An apparatus, comprising:
an upper glass layer;
an upper encapsulation layer;
a cell layer;
a lower encapsulation layer; and
a lower glass layer, wherein the upper glass layer, the upper encapsulation layer, the cell layer, the lower encapsulation layer, and the lower glass layer are disposed sequentially from top to bottom.

14. The apparatus according to claim 13, wherein the cell layer comprises a plurality of double-sided cells connected in series by a solder strip.

15. The apparatus according to claim 13, wherein the upper glass layer is provided with a first anti-reflection film layer on the upper surface and a first up-conversion thin film layer on the lower surface.

16. The apparatus according to claim 13, the lower glass layer is provided with a second up-conversion thin film layer on the upper surface and a second anti-reflection film layer on the lower surface.

17. The apparatus according to claim 13, wherein the first anti-reflection film layer and the second anti-reflection film layer are composed of one or more of SiO2, TiO2, SiNx, Al2O3, MgF2, and ZrO2.

18. The apparatus according to claim 13, wherein the first up-conversion thin film layer and the second up-conversion thin film layer are composed of a Yb3+, Er3+co-doped fluoride, a Yb3+, Tm3+co-doped fluoride, an Er3+single-doped fluoride, or a Tm3+single-doped fluoride.

19. The apparatus according to claim 13, wherein the first up-conversion thin film layer and the second up-conversion thin film layer are composed of a Yb3+, Er3+co-doped oxide, a Yb3+, Tm3+co-doped oxide, an Er3+single-doped oxide, or a Tm3+single-doped oxide.

20. A method for making a bifacial solar module, the method comprising:
applying a lower encapsulation layer on a lower glass layer to make a first module;
applying a cell layer on the first module to make a second module;
applying an upper encapsulation layer on the second module to make a third module; and
applying an upper glass layer on the third module to make a bifacial double glass solar module, wherein the upper glass layer, the upper encapsulation layer, the cell layer, the lower encapsulation layer, and the lower glass layer are disposed sequentially from top to bottom.
